(19) United States
(12) Patent Application Publication
(10) Pub. No.: US 2025/0219011 A1
(43) Pub. Date: Jul. 3, 2025

(54) CHUCK FOR WAFER BONDING DEVICE

(71) Applicant: SAMSUNG ELECTRONICS CO., LTD., SUWON-SI (KR)

(72) Inventors: Kyungmin Baek, Suwon-si (KR); Minwoo Rhee, Suwon-si (KR); Ilyoung Han, Suwon-si (KR); Jaeuk Sim, Suwon-si (KR); Joongha Lee, Suwon-si (KR); Kyeongbin Lim, Suwon-si (KR)

(21) Appl. No.: 18/892,761

(22) Filed: Sep. 23, 2024

(30) Foreign Application Priority Data
Jan. 2, 2024 (KR) 10-2024-0000199

(51) Int. Cl. H01L 23/00

(52) U.S. Cl. CPC H01L 24/74; H01L 2224/74; H01L 2924/3511

(57) ABSTRACT

A chuck for a wafer bonding device includes a body, a chuck portion installed on the body and that forms an internal space together with the body, and that includes a partition that divides the internal space, a valve installed on the body and that provides pneumatic pressure to each divided internal space, and a sensor disposed on the body at a lower portion of the partition. The valve adjusts and supplies pneumatic pressure to the divided internal space so that a shape of an upper surface of a deformable plate of the chuck portion is deformed.

### CROSS-REFERENCE TO RELATED APPLICATIONS

This application claims priority under 35 U.S.C. § 119 from Korean Patent Application No. 10-2024-0000199, filed on Jan. 2, 2024 in the Korean Intellectual Property Office, the contents of which are herein incorporated by reference in their entirety.

### TECHNICAL FIELD

Embodiments of the present inventive concept are directed to a chuck for a wafer bonding device.

### DISCUSSION OF THE RELATED ART

When a wafer-to-wafer (W2W) bonding process for bonding wafers is applied in a process of developing a flash memory device, such as a BVNAND, precise alignment is required between copper pads (Cu pads) present on bonding surfaces to electrically connect upper and lower wafers (WF).

However, various process or facility factors can affect bonding accuracy. In addition, the structural shape of a wafer is also a factor that affects bonding accuracy.

However, there is a clear difference in the degree of warpage that occurs in wafers being bonded, and in particular, in the case of wafers mounted on a lower chuck, saddle warpage can occur due to word lines piled up in a stepped manner.

Thus, performing a wafer bonding process in response to a warped wafer seated on a lower chuck, in which saddle warpage occurs, involves low bonding accuracy.

Therefore, there is a need to develop a device that may deform wafers in response to a warped wafer seated on a lower chuck, in which saddle warpage occurs.

### SUMMARY

An embodiment of the present inventive concept provides a chuck for a wafer bonding device that can implement asymmetrical deformation in response to deformation of a wafer in which saddle warpage occurs.

According to an embodiment of the present inventive concept, a chuck for a wafer bonding device includes a body, a chuck portion installed on the body and that forms an internal space together with the body and that includes a partition that divides the internal space, a valve installed on the body and that provides pneumatic pressure to each divided internal space, and a sensor disposed on the body at a lower portion of the partition. The valve adjusts and supplies pneumatic pressure to the divided internal space so that a shape of an upper surface of a deformable plate of the chuck portion is deformed.

According to an embodiment of the present inventive concept, a chuck for a wafer bonding device includes a body; a chuck portion installed on the body and that forms an internal space together with the body, and that includes partitions that divides the internal space into a plurality of regions; a plurality of valves installed on the body and that provides pneumatic pressure to each region of the plurality of regions; and a plurality of sensors disposed on the body at a lower portion of the partition. The body includes a plurality of inlets/outlets in which the plurality of valves are installed and a plurality of through-holes in which the plurality of sensors are installed, and lower ends of the partitions are inserted into and disposed inside the through-holes.

### BRIEF DESCRIPTION OF DRAWINGS

FIG. 1 illustrates a chuck for a wafer bonding device according to an embodiment.

FIG. 2 is a perspective view of a chuck for a wafer bonding device according to an embodiment.

FIG. 3 is a bottom perspective view of a chuck for a wafer bonding device according to an embodiment.

FIG. 4 illustrates an operation of a chuck for a wafer bonding device according to an embodiment.

FIGS. 5 and 6 illustrate deformation states of an upper surface of a deformable plate of a chuck portion according to pneumatic pressure provided to an internal space formed by a body and a chuck portion.

### DETAILED DESCRIPTION

Hereinafter, embodiments of the present inventive concept are described with reference to the accompanying drawings.

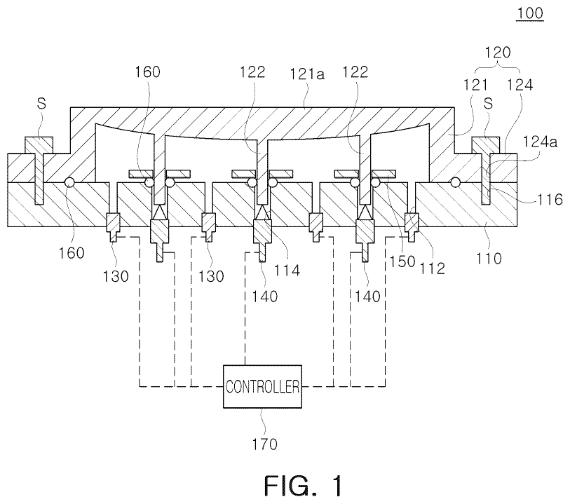

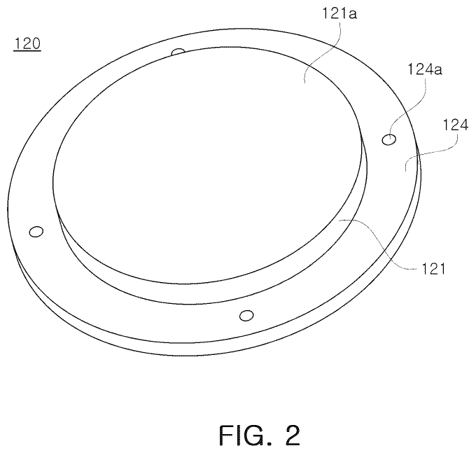

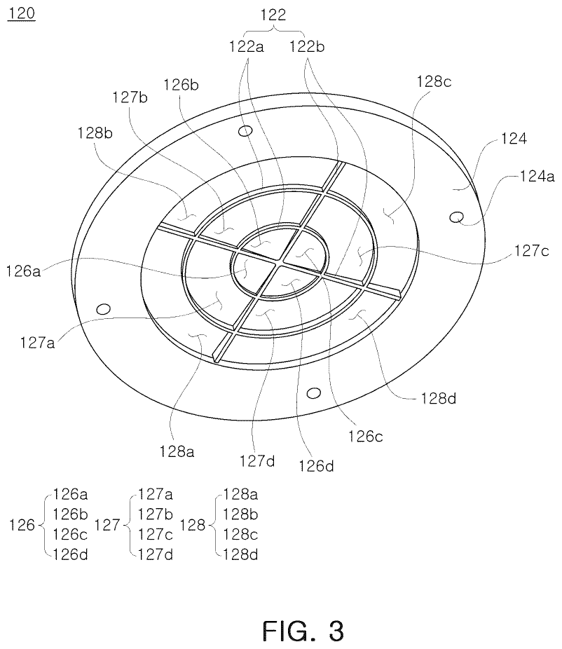

FIG. 1 illustrates a chuck for a wafer bonding device according to an embodiment, FIG. 2 is a perspective view of a chuck for a wafer bonding device according to an embodiment, and FIG. 3 is a bottom perspective view of a chuck for a wafer bonding device according to an embodiment.

Referring to FIGS. 1 to 3, a chuck 100 for a wafer bonding device according to an embodiment includes, for example, a body 110, a chuck portion 120, a valve 130, a sensor 140, a cover member 150, and a sealing member 160.

The body 110 may have a circular plate shape, for example. In addition, the body 110 is larger than the chuck portion 120 so that the chuck portion 120 can be fixedly installed. The valve 130 is installed in the body 110 and an inlet/outlet 112 is provided to supply pneumatic pressure to an internal space formed by the body 110 and the chuck portion 120. A plurality of inlets/outlets 112 are spaced apart from each other and correspond to a number of separated spaces formed by partitions 122 to be described below. A valve 130 is installed at the inlet/outlet 112, and pneumatic pressure is controlled by the valve 130. In addition, the body 110 is provided with a plurality of through-holes 114 into which the partitions 122 are inserted and in which the sensors 140 are installed, respectively. In addition, the body 110 includes a screw recess 116 for fixed installation of the chuck portion 120. A plurality of screw recesses 116 are spaced apart from each other in a circumferential direction.

The circumferential direction refers to a direction of rotation along an outer circumferential surface of the body 110.

The chuck portion 120 is fixedly installed on the body 110. For example, the chuck portion 120 includes a wafer adsorption portion 121 to which a wafer is adsorbed and an extension portion 124 that radially extends from the wafer adsorption portion 121. The chuck portion 120 can be fixedly coupled to the body 110 with a screw S, and the extension portion 124 includes a screw hole 124a into which the screw S is inserted. A wafer can be adsorbed on an upper surface of the wafer adsorption portion 121. In addition, the upper surface of the wafer adsorption portion 121 has a circular planar shape. The wafer adsorption portion 121 and the body 110 form an internal space. In addition, to partition the internal space, the partition 122, which extends toward the body 110, is provided on the bottom of the wafer adsorption portion 121. The partition 122 includes, for example, a circular wall portion 122a that has a circular ring shape and a vertical wall portion 122b that intersects with the circular wall portion 122a. For example, two circular wall portions 122a that have different diameters are spaced apart from each other, and four vertical wall portions 122b are spaced apart from each other. The internal space formed by the wafer adsorption portion 121 and the body 110 is divided into a first region 126 formed in the center, a second region 127 formed outside and around the first region 126, and a third region 128 formed outside and around the second region 127. In addition, the first region 126 is divided into, for example, a 1-1 region 126a, a 1-2 region 126b, a 1-3 region 126c, and a 1-4 region 126d by the vertical wall portions 122b. In addition, the second region 127 is divided into, for example, a 2-1 region 127a, a 2-2 region 127b, a 2-3 region 127c, and a 2-4 region 127d by the vertical wall portions 122b. In addition, the third region 128 is divided into, for example, a 3-1 region 128a, a 3-2 region 128b, a 3-3 region 128c, and a 3-4 region 128d by the vertical wall portions 122b. In this manner, since the wafer adsorption portion 121 is provided with the partition 122 that includes the circular wall portion 122a and the vertical wall portion 122b, the internal space formed by the wafer adsorption portion 121 and the body 110 is divided into a total of 12 spaces. Accordingly, different pneumatic pressures can be provided to the regions. Accordingly, the upper end of the wafer adsorption portion 121, that is, each region of a deformable plate 121a, can be deformed independently of each other. However, an embodiment in which the internal space formed by the wafer adsorption portion 121 and the body 110 is divided into a total of 12 spaces is described as an example, but, without being necessarily limited thereto, the internal space formed by the wafer adsorption portion 121 and the body 110 can be divided into regions fewer than 12 or more than 12 regions in other embodiments. In addition, the deformable plate 121a is thickest in the center and become thinner toward the edges. For example, the bottom of the deformable plate 121a is downwardly convex. In addition, a lower end of the partition 122 is inserted into the through-hole 114 of the body 110.

The valve 130 is installed in the body 110. For example, the valve 130 is installed in the inlet/outlet 112 of the body 110. For example, a plurality of valves 130 are provided, and as described above, the plurality of valves 130 are connected to the 12 separated regions, respectively. In addition, different pneumatic pressure can be provided to each region by the valve 130. Accordingly, the deformable plate 121a of the wafer adsorption portion 121 can be deformed asymmetrically rather than symmetrically. Accordingly, an upper surface of the deformable plate 121a can be deformed to correspond to the shape of the wafer in which a saddle warpage occurs. In addition, the valve 130 is connected to a pneumatic supply pipe that adjusts the pneumatic pressure. For example, the valve 130 is connected to a controller 170, and the controller 170 can adjust deformation of the upper surface of the deformable plate 121a by controlling the plurality of valves 130 respectively connected to the 12 separated regions.

The sensor 140 is installed in the body 110. For example, the sensor 140 can be installed in the through-hole 114 of the body 110. In addition, the sensor 140 detects a distance from the partition 122. For example, the sensor 140 is connected to the controller 170, and the controller 170 can determine a deformation state of the upper surface of the deformable plate 121a from the distance to the partition 122 extracted from a signal received from the sensor 140 and adjust the pneumatic pressure through the plurality of valves 130.

The cover member 150 is installed on the upper surface of the body 110 so that the partition 122 passes therethrough. For example, a plurality of cover members 150 are installed on the body 110 and are spaced apart from each other. The cover member 150 is installed on the body 110 to block air movement through the through-hole 114. For example, the cover member 150 has a plate shape.

The sealing member 160 is installed on the body 110 to block air movement. For example, a plurality of sealing members 160 are provided, and some of the sealing members 160 are disposed between the extension portion 124 of the chuck 120 and the upper surface of the body 110, and the others are disposed between the cover member 150 and body 110. Accordingly, air can be blocked from moving through a space between the body 110 and the chuck portion 120, and further, air can be blocked from moving through the through-hole 114.

As described above, the deformation of the upper surface of the deformable plate 121a can be adjusted by controlling the plurality of valves 130 respectively connected to the 12 separated regions. Accordingly, asymmetrical deformation of the upper surface of the deformable plate 121a can be implemented in response to deformation of the wafer in which saddle warpage occurs.

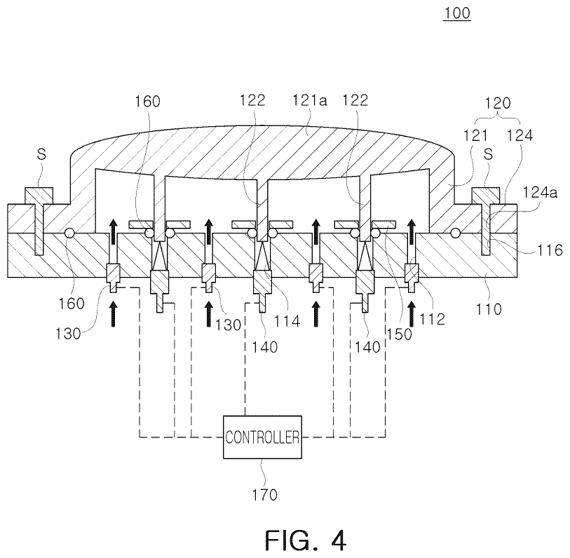

FIG. 4 illustrates an operation of a chuck for a wafer bonding device according to an embodiment.

Referring to FIG. 4, in an embodiment, different pneumatic pressures are respectively provided to the regions through the valve 130 in the inlet/outlet 112. Accordingly, as different pneumatic pressures are provided to the separate regions, the deformable plate 121a of the chuck portion 120 is deformed. At this time, the upper surface of the deformable plate 121a is deformed. In addition, the partition 122 moves inside the through-hole 114 due to the deformation of the deformable plate 121a. The sensor 140 detects a distance from the partition 122. Accordingly, the controller 170 recognizes a deformation state of the upper surface of the deformable plate 121a through information on the distance from the partition 122 provided by the sensor 140. Thereafter, based on the deformation state information of the wafer, the controller 170 can adjust the deformation state of the upper surface of the deformable plate 121a.

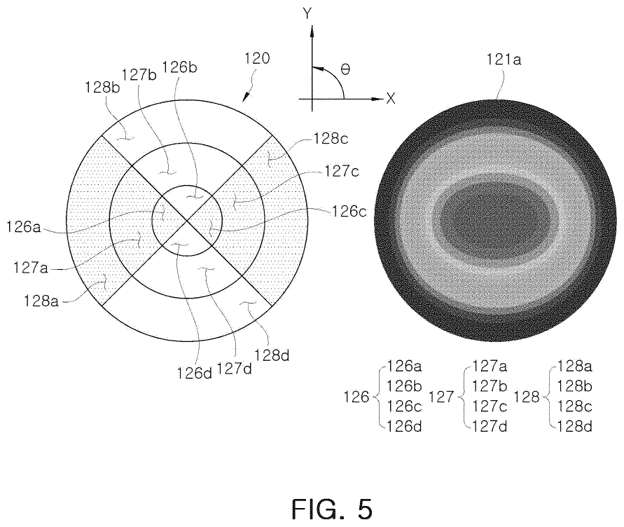

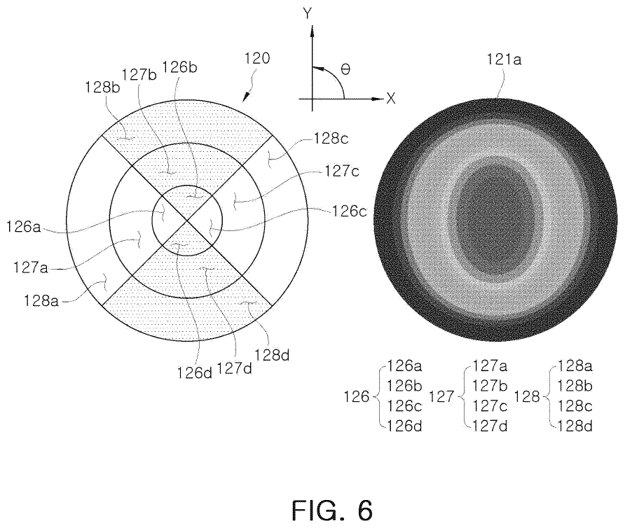

FIGS. 5 and 6 illustrate a deformation state of the upper surface of a deformable plate of a chuck portion according to pneumatic pressure provided to the internal space.

When pneumatic pressure is provided only to a space disposed in the X-axis, that is, the 1-1 region 126a, 2-1 region 127a, 3-1 region 128a, 1-3 region 126c, 2-3 region 127c, and 3-3 region 128c illustrated in FIG. 5, a vertical displacement of the upper surface of the deformable plate 121a appears as illustrated on the right side of FIG. 5. For example, the vertical displacement has an elliptical shape inclined in an X-axis direction, rather than a concentric circle shape. For example, a longer axis of the ellipse is aligned in the X-axis direction.

In addition, when pneumatic pressure is provided only to a space disposed in the Y-axis, that is, the 1-2 region 126b, 2-2 region 127b, 3-2 region 128b, 1-4 region 126d, 2-4 region 127d, and 3-4 region 128d illustrated in FIG. 6, a vertical displacement of the upper surface of the deformable plate 121a appears as illustrated on the right side of FIG. 6. For example, the vertical displacement has an elliptical shape inclined in a Y-axis direction, rather than a concentric circle shape. For example, a longer axis of the ellipse is aligned in the Y-axis direction.

Through this, when different pneumatic pressures are provided to the 12 separated spaces as described above, the 12 separated spaces can be independently controlled. Accordingly, asymmetric deformation of the chuck portion 120 can be implemented.

According to an embodiment, a chuck for a wafer bonding device is provided that implements asymmetrical deformation in response to deformation of a wafer in which saddle warpage occurs.

While embodiments have been illustrated and described above, it will be apparent to those skilled in the art that modifications and variations can be made without departing from the scope of embodiments of the present inventive concept as defined by the appended claims.

What is claimed is:

1. A chuck for a wafer bonding device, the chuck comprising:
a body;
a chuck portion installed on the body and that forms an internal space together with the body, and includes a partition that divides the internal space;
a valve installed on the body that provides pneumatic pressure to each divided internal space; and
a sensor disposed on the body at a lower portion of the partition,
wherein the valve adjusts and supplies pneumatic pressure to the divided internal space so that a shape of an upper surface of a deformable plate of the chuck portion is deformed.

2. The chuck of claim 1, wherein the partition includes a circular wall portion that has a circular ring shape and a vertical wall portion that intersects with the circular wall portion.

3. The chuck of claim 1, wherein the chuck portion includes a wafer adsorption portion and an extension portion that radially extends from the wafer adsorption portion, wherein a wafer is adsorbed to an upper surface of the wafer adsorption portion.

4. The chuck of claim 3, wherein the wafer adsorption portion includes the deformable plate whose upper surface has a circular planar shape.

5. The chuck of claim 4, wherein the partition extends from a bottom of the deformable plate.

6. The chuck of claim 4, wherein a lower end of the partition is inserted into and disposed inside a through-hole formed in the body.

7. The chuck of claim 6, further comprising a cover member that covers the through-hole and allows the partition to pass therethrough.

8. The chuck of claim 7, further comprising a sealing member disposed between the cover member and the through-hole.

9. The chuck of claim 1, wherein
the valve and the sensor are connected to a controller, and
the controller determines a deformation state of the upper surface of the deformable plate from a distance to the partition extracted from a signal received from the sensor, and adjusts a shape of the upper surface of the deformable plate by adjusting the pneumatic pressure.

10. The chuck of claim 1, wherein the deformable plate has a thickness that decreases from a center toward an edge.

11. The chuck of claim 10, wherein a bottom of the deformable plate is downwardly convex.

12. The chuck of claim 1, further comprising a sealing member disposed between the body and the chuck portion.

13. The chuck of claim 1, wherein the internal space formed by the body and the chuck portion and partitioned by the partition includes a first region disposed in a center of the chuck portion, a second region disposed outside and around the first region, and a third region disposed outside and around the second region.

14. The chuck of claim 13, wherein the first region includes a 1-1 region, a 1-2 region disposed adjacent to the 1-1 region, a 1-3 region disposed adjacent to the 1-2 region, and a 1-4 region disposed between the 1-1 region and the 1-3 region, that are partitioned by a circular wall portion of the partition and a vertical wall portion of the partition.

15. The chuck of claim 14, wherein the second region includes a 2-1 region disposed outside the 1-1 region, a 2-2 region disposed outside the 1-2 region, a 2-3 region disposed outside the 1-3 region, and a 2-4 region disposed outside the 1-4 region.

16. The chuck of claim 15, wherein the third region includes a 3-1 region disposed outside the 2-1 region, a 3-2 region disposed outside the 2-2 region, a 3-3 region disposed outside the 2-3 region, and a 3-4 region disposed outside the 2-4 region.

17. A chuck for a wafer bonding device, the chuck comprising:
a body;
a chuck portion installed on the body and that forms an internal space together with the body, and that includes partitions that divides the internal space into a plurality of regions;
a plurality of valves installed on the body and that provides pneumatic pressure to each region of the plurality of regions; and
a plurality of sensors disposed on the body at a lower portion of the partition,
wherein the body includes a plurality of inlets/outlets in which the plurality of valves are installed and a plurality of through-holes in which the plurality of sensors are installed, and
lower ends of the partitions are inserted into and disposed inside the through-holes.

18. The chuck of claim 17, further comprising:
a controller connected to the plurality of valves and the plurality of sensors,
wherein the controller adjusts and supplies pneumatic pressure to each region of the plurality of regions by controlling a valve of the plurality of valves that corresponds to each region based on a distance to the partition extracted from a signal received from a corresponding sensor of the plurality of sensors,
wherein a shape of an upper surface of a deformable plate of the chuck portion is deformed.

19. The chuck of claim 17, wherein the partition includes a circular wall portion that has a circular ring shape and a vertical wall portion that intersects with the circular wall portion, wherein the circular wall portion and the vertical wall portion divide the internal space into the plurality of regions.

20. The chuck of claim 17, wherein the chuck portion includes a wafer adsorption portion and an extension portion that radially extends from the wafer adsorption portion, wherein a wafer is adsorbed to an upper surface of the wafer adsorption portion, and wherein the wafer adsorption portion includes a deformable plate whose upper surface has a circular planar shape.
